(19) United States
(12) Patent Application Publication
(10) Pub. No.: US 2025/0364925 A1
(43) Pub. Date: Nov. 27, 2025

(54) ELECTROSTATIC CHUCK

(71) Applicant: TOTO LTD., Fukuoka (JP)

(72) Inventors: Jumpei UEFUJI, Fukuoka (JP); Tomoki UMETSU, Fukuoka (JP); Tatsuya MORI, Fukuoka (JP); Masafumi IKEGUCHI, Fukuoka (JP); Kensuke SUZUKI, Fukuoka (JP)

(21) Appl. No.: 19/213,366

(22) Filed: May 20, 2025

(30) Foreign Application Priority Data
May 23, 2024 (JP) 2024-083859

(51) Int. Cl. H02N 13/00; B23Q 3/15

(52) U.S. Cl. CPC H02N 13/00; B23Q 3/15

(57) ABSTRACT

An electrostatic chuck 10 includes a dielectric substrate 100 which includes a first part 101 including a placement surface and a second part 102 which protrudes from an outer circumferential edge of the first part 101 further towards an outer circumferential side, an internal electrode 140 provided inside the second part 102, a feed terminal 160 provided in a position which is not overlapped with the internal electrode 140 in top view, and a bypass portion 150 which is provided inside the dielectric substrate 100 and electrically connects the feed terminal 160 and the internal electrode 140.

### CROSS-REFERENCE TO RELATED APPLICATION

This application is based upon and claims the benefit of priority from Japanese Patent Application No. 2024-083859 filed on May 23, 2024, the entire contents of which are incorporated herein by reference.

### FIELD

The present invention relates to an electrostatic chuck.

### BACKGROUND

For example, in a semiconductor manufacturing apparatus such as an etching apparatus, an electrostatic chuck is provided as an apparatus configured to attract and hold a wafer such as a silicon wafer to be processed. The electrostatic chuck includes a dielectric substrate in which an attraction electrode is provided and a base plate which supports the dielectric substrate, and has a configuration in which these are joined to each other. When a voltage is applied to the attraction electrode, an electrostatic force is generated, and the wafer placed on the dielectric substrate is attracted and held.

During the processing of the wafer, an annular member referred to as a focus ring or the like is arranged around the wafer. As described in Japanese Patent Laid-Open No. 2023-177720, the dielectric substrate may be provided with a rim portion for placing such an annular member. A part on which the wafer such as the silicon wafer to be processed is placed in the dielectric substrate will be hereinafter also referred to as a first part. The above-described rim portion provided in the dielectric substrate will be hereinafter also referred to as a second part. The second part (rim portion) is a part which protrudes from an outer circumferential edge of the first part further towards an outer circumferential side and which is thinner than the first part.

### SUMMARY

As described in Japanese Patent Laid-Open No. 2023-177720, an internal electrode is provided inside the second part (rim portion). The internal electrode may be provided as, for example, an “attraction electrode” configured to generate an attraction force with the annular member, or may be provided as an “RF electrode” configured to generate plasma to be pulled towards the wafer. A feed terminal for feeding power to this internal electrode has been provided in a position overlapped with the internal electrode in the second part in top view in related art. In a case where the feed terminal is arranged in such a position, due to a reason that an air pressure around the feed terminal becomes lower than atmospheric pressure or the like, it is conceivable that discharge is likely to occur.

The present invention has been made in view of the above-mentioned issue and is aimed to provide an electrostatic chuck which can prevent discharge at a feed terminal.

To address the above-described issue, an electrostatic chuck according to an aspect of the present invention includes a dielectric substrate which includes a first part including a placement surface on which an object to be attracted is placed, and a second part which protrudes from an outer circumferential edge of the first part further towards an outer circumferential side and which is thinner than the first part, an internal electrode provided inside the second part, a feed terminal provided in a position which is not overlapped with the internal electrode when viewed from a direction perpendicular to the placement surface, and a bypass portion which is provided inside the dielectric substrate and which electrically connects the feed terminal and the internal electrode.

The position overlapped with the internal electrode in top view is a position in the vicinity of an edge portion on the outer circumferential side in the dielectric substrate and is a position where discharge is relatively likely to occur since an ambient air pressure is low. In view of the above, in the electrostatic chuck having the above-described configuration, a degree of freedom in an arrangement of the feed terminal is increased by providing the bypass portion, and then the feed terminal is arranged in the position which is not overlapped with the internal electrode in top view. Since the feed terminal is arranged by avoiding the position where discharge is likely to occur, discharge at the feed terminal can be prevented.

According to the aspect of the present invention, it is possible to provide an electrostatic chuck which can prevent discharge at the feed terminal.

### BRIEF DESCRIPTION OF THE DRAWINGS

FIG. 1 is a cross sectional view schematically illustrating a configuration of an electrostatic chuck according to a first embodiment;

FIG. 2 is an enlarged view illustrating a part of the configuration of the electrostatic chuck according to the first embodiment in detail;

FIG. 3 schematically illustrates a configuration of an internal electrode, a bypass portion, and the like in top view;

FIG. 4 is an enlarged view illustrating a part of the configuration of the electrostatic chuck according to a second embodiment in detail; and

FIG. 5 schematically illustrates a configuration of the internal electrode, the bypass portion, and the like in top view.

### DETAILED DESCRIPTION

Hereinafter, the present embodiment will be described with reference to the accompanying drawings. To ease understanding of the descriptions, in each drawing, the same components are denoted by the same reference signs as much as possible, and duplicate descriptions are not repeated.

A first embodiment will be described. An electrostatic chuck 10 according to the present embodiment is configured to attract and hold a wafer W set as a process target by an electrostatic force inside a semiconductor manufacturing apparatus such as, for example, an etching apparatus which is not illustrated in the drawing. The wafer W that is an object to be attracted is, for example, a silicon wafer. The electrostatic chuck 10 may be used in an apparatus other than the semiconductor manufacturing apparatus.

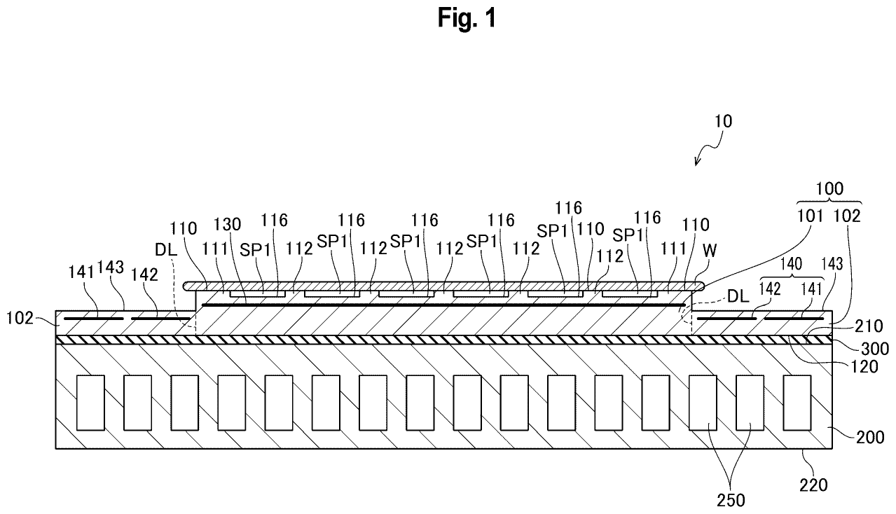

FIG. 1 is a cross sectional view schematically illustrating a configuration of the electrostatic chuck 10 in a state in which the wafer W is attracted and held. The electrostatic chuck 10 includes a dielectric substrate 100 and a base plate 200.

The dielectric substrate 100 is a substantially disk-shaped member formed of a ceramic sintered body. The dielectric substrate 100 contains, for example, highly pure aluminum oxide (Al₂O₃), but may contain other materials. A ceramics purity or type, an additive, or the like in the dielectric substrate 100 may be appropriately set by taking into account plasma resistance or the like needed for the dielectric substrate 100 in the semiconductor manufacturing apparatus.

A surface 110 on an upper side in FIG. 1 in the dielectric substrate 100 serves as a “placement surface” on which the wafer W is placed. A surface 120 on a lower side in FIG. 1 in the dielectric substrate 100 serves as a “surface to be joined” which is joined to the base plate 200 via a joining layer 300. A perspective in a case where the electrostatic chuck 10 is viewed from the surface 110 side along a direction perpendicular to the surface 110 will also be hereinafter expressed as “top view”.

The dielectric substrate 100 has a first part 101 and a second part 102. The first part 101 is a part having a substantially cylindrical shape extending from the surface 110 towards a lower side of FIG. 1 to the surface 120. The first part 101 described above can be mentioned as a part including the surface 110 serving as the placement surface in the dielectric substrate 100.

The second part 102 is a ring-shaped part protruding from an outer circumferential edge of the first part 101 further towards an outer circumferential side and is a part also referred to as a “rim portion” of the dielectric substrate 100. In FIG. 1, a boundary between the first part 101 and the second part 102 is indicated by a dotted line DL. The second part 102 is thinner than the first part 101. The surface 120 described above is a lowermost surface of the first part 101 in FIG. 1, and is also a lowermost surface of the second part 102. An uppermost surface 143 of the second part 102 is in a position lower than the surface 110 in FIG. 1.

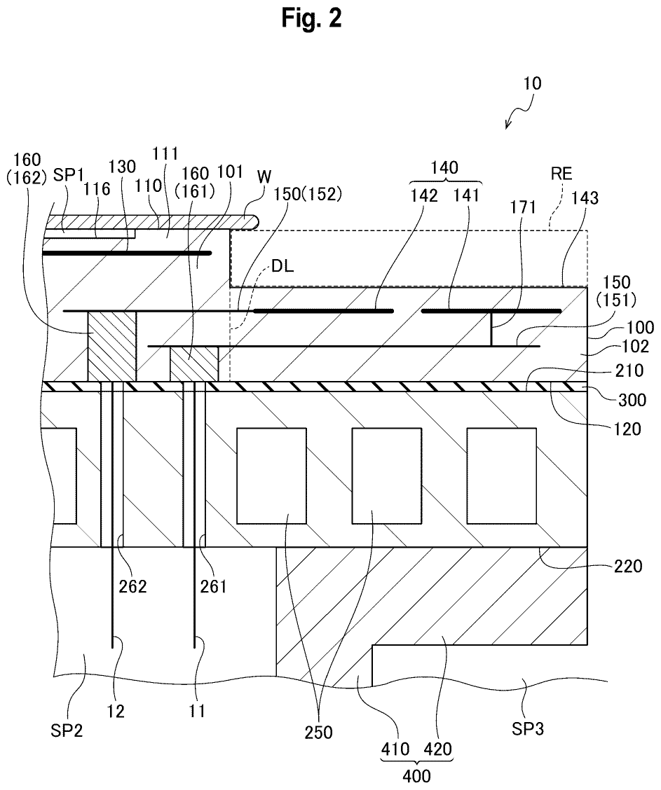

As illustrated in FIG. 2, when processing of the wafer W is performed in the semiconductor manufacturing apparatus, an annular member RE referred to as a focus ring or the like is arranged around the wafer W. The surface 143 of the second part 102 serves as a part supporting the above-described annular member RE from below. The surface 143 is a surface parallel to the surface 110.

An attraction electrode 130 is provided inside the first part 101 in the dielectric substrate 100. The attraction electrode 130 is a thin planar layer made of a metallic material such as, for example, tungsten, and is arranged so as to be parallel to the surface 110. As a material of the attraction electrode 130, molybdenum, platinum, palladium, and the like may be used in addition to tungsten. When a voltage is applied to the attraction electrode 130 from the outside via a feed line which is not illustrated in the drawing, an electrostatic force is generated between the surface 110 and the wafer W, and according to this, the wafer W is attracted and held. As a configuration of the above-described feed line, various configurations in related art can be adopted. The attraction electrode 130 may be just a single attraction electrode provided as so-called a “monopolar” electrode as in the present embodiment, but may also include two attraction electrodes provided as so-called “bipolar” electrodes.

An internal electrode 140 is provided inside the second part 102 in the dielectric substrate 100. The internal electrode 140 is a thin planar layer made of a material similar to that of the attraction electrode 130 and is arranged so as to be parallel to the surface 143. When a voltage is applied to the internal electrode 140 from the outside via a feed line which is not illustrated in the drawing in FIG. 1, an electrostatic force is generated between the surface 143 and the annular member RE, and according to this, the annular member RE is attracted and held. The internal electrode 140 includes a first internal electrode 141 and a second internal electrode 142 which are provided as so-called “bipolar” electrodes. Instead of such a configuration, a configuration may be adopted in which the internal electrode 140 is provided as a “monopolar” electrode. A specific configuration of the internal electrodes 140 and the feed line connected to these will be described later.

As illustrated in FIG. 1, a space SP1 is formed between the dielectric substrate 100 and the wafer W. When a process such as etching is performed in the semiconductor manufacturing apparatus, a helium gas for temperature regulation is supplied to the space SP1 from the outside via a gas hole which is not illustrated in the drawing. When the helium gas is caused to be present between the dielectric substrate 100 and the wafer W, a thermal resistance between the dielectric substrate 100 and the wafer W is regulated, and according to this, a temperature of the wafer W is maintained at an appropriate temperature. It is noted that the gas for temperature regulation supplied to the space SP1 may be a gas of a type different from Helium.

A seal ring 111 and dots 112 are provided on the surface 110 which serves as the placement surface, and the space SP1 described above is formed around the seal ring 111 and the dots 112.

The seal ring 111 is a wall which defines the space SP1 in a position corresponding to an outermost circumference. An upper end of the seal ring 111 becomes a part of the surface 110 and abuts against the wafer W. It is noted that the seal ring 111 may include a plurality of seal rings 111 provided so as to divide the space SP1. With such a configuration, a pressure of the helium gas in each of the spaces SP1 can be individually regulated, and a surface temperature distribution of the wafer W during the process can be set to be close to uniformity.

A part denoted by reference sign “116” in FIG. 1 is a bottom of the space SP1. Hereinafter, this part may also be referred to as a “bottom 116”. The seal ring 111 is formed as a result of recessing a part of the surface 110 to a position of the bottom 116 together with the dots 112 which will be described next.

Each of the dots 112 is a circular protrusion which protrudes from the bottom 116. The dots 112 are provided in plurality, and are substantially uniformly distributed and arranged on the placement surface of the dielectric substrate 100. An upper end of each of the dots 112 becomes a part of the surface 110 and abuts against the wafer W. By providing the plurality of such dots 112, warping of the wafer W can be restrained.

The base plate 200 is a substantially disk-shaped member which supports the dielectric substrate 100. The base plate 200 is made of, for example, a metallic material such as aluminum. A surface 210 on the upper side in FIG. 1 in the base plate 200 serves as a “surface to be joined” which is joined to the dielectric substrate 100 via the joining layer 300. An outer shape of the surface 210 in top view substantially matches an outer shape of the second part 102 in top view.

The joining layer 300 is a layer provided between the dielectric substrate 100 and the base plate 200 to join those components. The joining layer 300 is obtained by causing an adhesive made of an insulating material to be cured. According to the present embodiment, a silicone adhesive is used as the above-described adhesive. It is noted however that the joining layer 300 may be obtained by causing a different type of adhesive to be cured. In any case, in order that a thermal resistance between the dielectric substrate 100 and the base plate 200 is reduced, a material with a highest possible thermal conductivity is preferably used as the material of the joining layer 300.

An insulating film may be formed on a surface of the base plate 200. As the insulating film, for example, an alumina film formed by thermal splaying can be used. When the surface of the base plate 200 is covered by the insulating film, it is possible to increase a withstand voltage of the base plate 200.

A coolant flow path 250 through which a coolant flows is formed inside the base plate 200. When the process such as etching is performed in the semiconductor manufacturing apparatus, the coolant is supplied from the outside to the coolant flow path 250, and according to this, the base plate 200 is cooled down. Heat generated in the wafer W during the process is transferred to the coolant via the helium gas in the space SP1, the dielectric substrate 100, and the base plate 200, and the heat is exhausted to the outside together with the coolant. The supply and exhaustion of the coolant to and from the coolant flow path 250 are performed via openings which are not illustrated in the drawing and which are formed in a surface 220 opposite to the surface 210 in the base plate 200. The coolant flow path 250 is formed to pass through not only in a range overlapped with the first part 101 in top view but also in a range overlapped with the second part 102. For this reason, not only the wafer W but also the annular member RE are cooled down by the coolant passing through the coolant flow path 250.

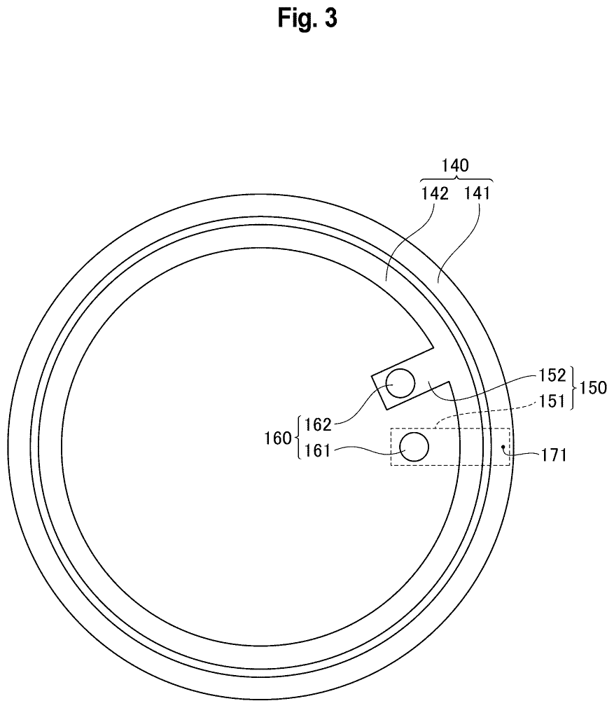

A specific configuration of the internal electrodes 140 and the feed line connected to these will be described with reference to FIG. 2 and FIG. 3. In FIG. 2, a configuration of the second part 102 of the dielectric substrate 100 and its neighboring part is illustrated as a schematic cross sectional view. FIG. 3 schematically illustrates the configuration of the internal electrodes 140 and the like in top view.

As described above, the internal electrode 140 of the present embodiment is configured as a “bipolar” electrode, and includes the first internal electrode 141 and the second internal electrode 142. As illustrated in FIG. 3, in top view, these are formed so as to extend in concentric circles. The first internal electrode 141 is arranged on the outer circumferential side, and the second internal electrode 142 is arranged on an inner circumferential side. The first internal electrode 141 and the second internal electrode 142 are provided in the same height position as each other. The term “height position” refers to a position along the direction perpendicular to the surface 110 serving as the placement surface.

A feed terminal 160 is embedded in the surface 120 of the dielectric substrate 100. The feed terminal 160 is a metallic part for accepting power supplied from the outside to the internal electrode 140. The feed terminal 160 is individually provided corresponding to each of the first internal electrode 141 and the second internal electrode 142. The feed terminal 160 provided corresponding to the first internal electrode 141 will be hereinafter also referred to as a “first feed terminal 161”. The feed terminal 160 provided corresponding to the second internal electrode 142 will be hereinafter also referred to as a “second feed terminal 162”.

According to the present embodiment, one first feed terminal 161 is provided corresponding to the first internal electrode 141, but a plurality of first feed terminals 161 may be provided. Similarly, one second feed terminal 162 is provided corresponding to the second internal electrode 142, but a plurality of second feed terminals 162 may be provided.

A through hole 261 is formed in a part overlapped with the first feed terminal 161 in top view in the base plate 200. A bus bar 11 is communicatively inserted from the lower side in the through hole 261, and one end of the bus bar 11 is connected to the first feed terminal 161. The power from the outside is supplied to the first feed terminal 161 via the bus bar 11.

Similarly, a through hole 262 is formed in a part overlapped with the second feed terminal 162 in top view in the base plate 200. A bus bar 12 is communicatively inserted from the lower side in the through hole 262, and one end of the bus bar 12 is connected to the second feed terminal 162. The power from the outside is supplied to the second feed terminal 162 via the bus bar 12.

According to the present embodiment, the first internal electrode 141 and the second internal electrode 142 are provided in the second part 102, and the first feed terminal 161 and the second feed terminal 162 are provided in the first part 101. For this reason, the feed terminal 160 is provided in a position which is not overlapped with the internal electrode 140 in top view.

A bypass portion 150 is provided inside the dielectric substrate 100 to electrically connect the feed terminal 160 and the internal electrode 140 described above. The bypass portion 150 includes a first bypass portion 151 and a second bypass portion 152. Each of these is a thin planar layer made of a material similar to those of the attraction electrode 130 and the internal electrode 140 and is arranged so as to be parallel to the surface 110.

The first bypass portion 151 electrically connects the first feed terminal 161 and the first internal electrode 141. The first bypass portion 151 is in a position on the first feed terminal 161 side relative to the first internal electrode 141 in the direction perpendicular to the placement surface, that is, a position on the lower side relative to the first internal electrode 141 and the second internal electrode 142 in FIG. 2. As illustrated in FIG. 3, the first bypass portion 151 is formed so as to extend from the position overlapped with the first internal electrode 141 to a position overlapped with the first feed terminal 161 in top view.

A via 171 electrically connects the first internal electrode 141 and the first bypass portion 151. The via 171 is obtained by filling the inside of the through hole formed so as to extend from the first internal electrode 141 to the first bypass portion 151 with a conductive material such as tungsten.

According to the present embodiment, a bottomed hole is formed in the surface 120 of the dielectric substrate 100, and the first feed terminal 161 is embedded in the hole in a state in which the first bypass portion 151 is exposed at a bottom of the hole. With such a configuration, the first feed terminal 161 and the first bypass portion 151 are directly connected. Instead of such a configuration, the first feed terminal 161 and the first bypass portion 151 may be electrically connected through a via similar to the via 171, for example.

The second bypass portion 152 electrically connects the second feed terminal 162 and the second internal electrode 142. The second bypass portion 152 is formed in the same height position as the second internal electrode 142. The second bypass portion 152 is formed so as to extend in a straight line from the inner circumferential side of the second internal electrode 142 to a position overlapped with the second feed terminal 162 in top view. The second bypass portion 152 is formed at the same time as the second internal electrode 142 through screen printing, for example, when the second internal electrode 142 is formed. For convenience of the illustration, in FIG. 2, the second bypass portion 152 is depicted as if the second bypass portion 152 is thinner than the second internal electrode 142, but in actuality, these thicknesses are the same as each other.

According to the present embodiment, a bottomed hole is formed in the surface 120 of the dielectric substrate 100, and the second feed terminal 162 is embedded in the hole in a state in which the second bypass portion 152 is exposed at a bottom of the hole. With such a configuration, the second feed terminal 162 and the second bypass portion 152 are directly connected. A dimension of the second feed terminal 162 in an up and down direction in FIG. 2 is larger than a dimension of the first feed terminal 161 in the same direction. Instead of such a configuration, the second feed terminal 162 and the second bypass portion 152 may be electrically connected through a via similar to the via 171, for example.

As described above, in the electrostatic chuck 10 according to the present embodiment, the feed terminal 160 is provided in the position which is not overlapped with the internal electrode 140 in top view, and the feed terminal 160 and the internal electrode 140 are electrically connected via the bypass portion 150.

A reason why such a configuration is adopted will be described. FIG. 2 also illustrates a support base 400 provided to the semiconductor manufacturing apparatus in addition to the electrostatic chuck 10. The support base 400 is a member for supporting the electrostatic chuck 10 from the lower side. The electrostatic chuck 10 is fastened and fixed to the support base 400 by a bolt which is not illustrated in the drawing, for example.

The support base 400 includes a cylindrical portion 410 and a flange portion 420. The cylindrical portion 410 is a part having a substantially cylindrical shape, and a central axis of the cylindrical portion 410 matches a central axis of the electrostatic chuck 10. An internal diameter of the cylindrical portion 410 is approximately the same as or slightly larger than a diameter of the surface 110 and is smaller than outer diameters of the second part 102 and the base plate 200.

The flange portion 420 is a circular flange formed so as to protrude from an edge portion on the electrostatic chuck 10 in the cylindrical portion 410 towards the outer circumferential side. An outer diameter of the flange portion 420 is approximately equal to the outer diameters of the second part 102 and the base plate 200. The flange portion 420 is fastened and fixed to the base plate 200 in a state in which the flange portion 420 abuts against the surface 220 of the base plate 200 from the lower side.

An O-ring which is not illustrated in the drawing is sandwiched in between the flange portion 420 and the base plate 200. According to this, airtightness of a space SP2 inside the cylindrical portion 410 is maintained. During the processing and the like of the wafer W, while the pressure in a space SP3 around the electrostatic chuck 10 is decreased, a pressure inside the space SP2 is kept at atmospheric pressure.

If the feed terminal 160 is provided in a position overlapped with the internal electrode 140 in top view, the feed terminal 160 and an electrical path connected to this are exposed to the space SP3. The space SP3 is depressurized as described above and has a pressure range where discharge is relatively likely to occur according to Paschen's law. For this reason, when power is fed to the internal electrode 140 via the feed terminal 160 or the like, it is conceivable that discharge is likely to occur.

In view of the above, in the electrostatic chuck 10 according to the present embodiment, the degree of freedom in the arrangement of the feed terminal 160 is increased by providing the bypass portion 150, and then the feed terminal 160 is arranged in the position which is not overlapped with the internal electrode 140 in top view. Specifically, the feed terminal 160 is provided in the first part 101 to be arranged in the space SP2 at atmospheric pressure, so that it is possible to prevent occurrence of discharge at the feed terminal 160, the bus bars 11 and 12, and the like.

An entirety of the feed terminal 160 of the present embodiment is provided in the first part 101, but only a part of the feed terminal 160 may be provided in the first part 101. For example, a part of the first feed terminal 161 may be provided in the first part 101, and a remaining part of the first feed terminal 161 may be provided in the second part 102. In any case, the entirety of the first feed terminal 161 and the second feed terminal 162 are preferably arranged in the space SP2 at atmospheric pressure.

According to the present embodiment, the first bypass portion 151 connected to the first internal electrode 141 on the outer circumferential side is in a height position different from the first internal electrode 141. Specifically, the first bypass portion 151 is in a position on the lower side in FIG. 2 relative to the first internal electrode 141. By providing the first bypass portion 151 in such a height position, without interfering with the second internal electrode 142 on the inner circumferential side, the first bypass portion 151 can be freely routed up to the first feed terminal 161 further on the inner circumferential side. It is noted that the first bypass portion 151 may be arranged in a position on the upper side relative to the first internal electrode 141 in FIG. 2.

According to the present embodiment, the first bypass portion 151 and the second bypass portion 152 are in height positions different from each other. Specifically, while the first bypass portion 151 is in the position on the lower side relative to the first internal electrode 141 as described above, the second bypass portion 152 is in the same height position as the first internal electrode 141 and the second internal electrode 142. Since it becomes possible to form the second internal electrode 142 and the second bypass portion 152 at the same time, the manufacturing costs can be reduced. Since a via with a small resistance does not need to be present between the second internal electrode 142 and the second bypass portion 152, an advantage is attained that heat generation at a connection portion between those components can be suppressed.

It is noted that even when the internal electrode 140 is provided as a monopolar electrode instead of bipolar electrodes, the above-described configuration can be adopted. That is, the bypass portion 150 which extends from the internal electrode 140 may be provided in the same height position as the monopolar internal electrode 140. In this case too, the feed terminal 160 connected to the bypass portion 150 is preferably provided in a position which is not overlapped with the internal electrode 140 in top view and is more preferably provided in the first part 101.

The internal electrode 140 may be provided as an attraction electrode configured to attract and hold the annular member RE as in the present embodiment, but may be provided as an “RF electrode” configured to generate plasma to be pulled towards the wafer W.

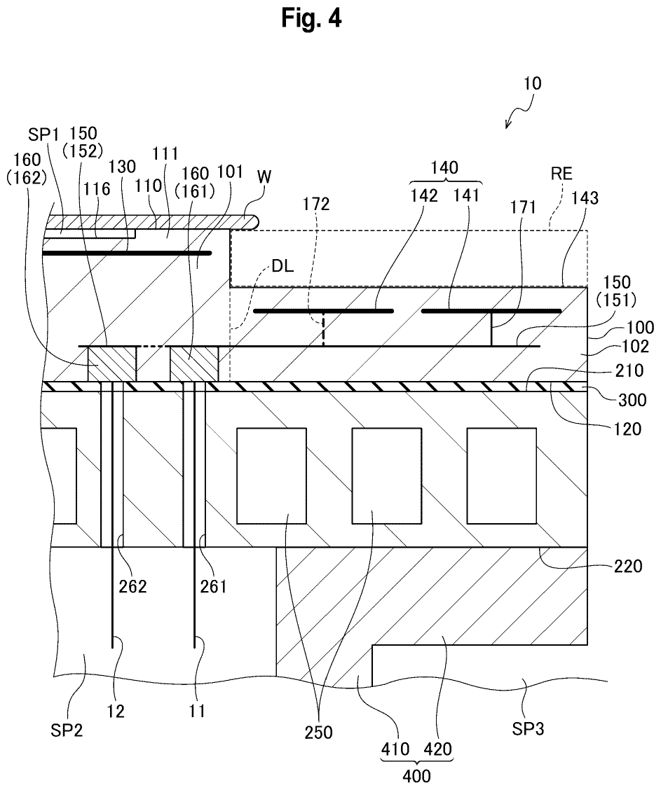

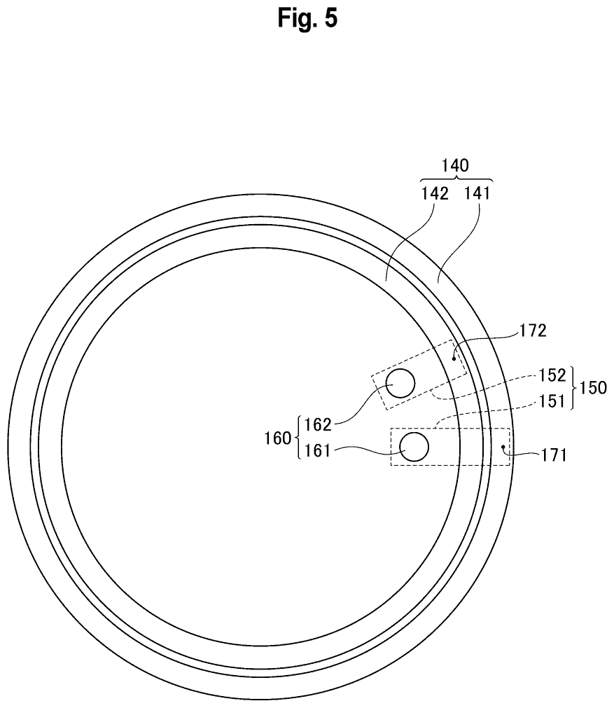

A second embodiment will be described with reference to FIG. 4 and FIG. 5. Hereinafter, an aspect different from the first embodiment will be mainly described, and descriptions on an aspect common to the first embodiment are not repeated as appropriate. FIG. 4 illustrates the configuration of the electrostatic chuck 10 according to the present embodiment depicted from a perspective similar to that of FIG. 2. FIG. 5 illustrates the configuration of the electrostatic chuck 10 according to the present embodiment depicted from a perspective similar to that of FIG. 3.

The electrostatic chuck 10 according to the present embodiment is different from the first embodiment in the height position of the second bypass portion 152. The second bypass portion 152 of the present embodiment is in the same height position as the first bypass portion 151. The second internal electrode 142 and the second bypass portion 152 are electrically connected by a via 172. The via 172 is obtained by filling the inside of the through hole formed so as to extend from the second internal electrode 142 to the second bypass portion 152 with a conductive material such as tungsten.

According to the present embodiment, since the first bypass portion 151 and the second bypass portion 152 are in the same height position as each other, the dimension of the second feed terminal 162 in the up and down direction in FIG. 4 is the same as the dimension of the first feed terminal 161 in the same direction. As a result, as the second feed terminal 162, it is possible to use a part with the same shape as the first feed terminal 161. In this manner, manufacturing costs of the electrostatic chuck 10 can be suppressed by sharing some parts.

The present embodiment has been described above with reference to the specific examples. However, the present disclosure is not limited to these specific examples. Configurations obtained by adding appropriate design modifications to these specific examples by a person skilled in the art are also within the scope of the present disclosure as long as the configurations have a feature of the present disclosure. Each of the elements included in each of the specific examples described above and arrangements, conditions, shapes, and the like of the elements are not limited to those illustrated and can be modified as appropriate. For each of the elements included in each of the specific examples described above, a combination can be appropriately changed as long as a technical contradiction does not occur.

What is claimed is:

1. An electrostatic chuck comprising:
a dielectric substrate which includes a first part including a placement surface on which an object to be attracted is placed, and a second part which protrudes from an outer circumferential edge of the first part further towards an outer circumferential side and which is thinner than the first part;
an internal electrode provided inside the second part;
a feed terminal provided in a position which is not overlapped with the internal electrode when viewed from a direction perpendicular to the placement surface; and
a bypass portion which is provided inside the dielectric substrate and which electrically connects the feed terminal and the internal electrode.

2. The electrostatic chuck according to claim 1, wherein
the feed terminal is provided in the first part.

3. The electrostatic chuck according to claim 2, wherein
the bypass portion is in the same height position as the internal electrode.

4. The electrostatic chuck according to claim 1, wherein
the internal electrode includes a first internal electrode and a second internal electrode provided in the same height position as each other,
the feed terminal includes a first feed terminal and a second feed terminal, and
the bypass portion includes
a first bypass portion which electrically connects the first feed terminal and the first internal electrode, and
a second bypass portion which electrically connects the second feed terminal and the second internal electrode.

5. The electrostatic chuck according to claim 4, wherein
the first internal electrode is in a position on the outer circumferential side relative to the second internal electrode, and
the first bypass portion is in a different height position from the first internal electrode.

6. The electrostatic chuck according to claim 5, wherein
in the direction perpendicular to the placement surface,
the first bypass portion is in a position on the first feed terminal side relative to the first internal electrode.

7. The electrostatic chuck according to claim 5, wherein
the second bypass portion is in a different height position from the first bypass portion.

8. The electrostatic chuck according to claim 7, wherein
the second bypass portion is in the same height position as the second internal electrode.

9. The electrostatic chuck according to claim 5, wherein
the second bypass portion is in the same height position as the first bypass portion.
